(19) United States
(12) Patent Application Publication
(10) Pub. No.: US 2026/0006873 A1
(43) Pub. Date: Jan. 1, 2026

(54) FABRICATION OF RIBBON CFETS WITH OPTIMIZED NMOS AND PMOS CHANNEL MATERIALS

(71) Applicant: Intel Corporation, Santa Clara, CA (US)

(72) Inventors: Guowei Xu, Portland, OR (US); Robin Chao, Portland, OR (US); Chia-Ching Lin, Portland, OR (US); Tao Chu, Portland, OR (US); Kan Zhang, Hillsboro, OR (US); Yang Zhang, Rio Rancho, NM (US); Lin Hu, Portland, OR (US); Ting-Hsiang Hung, Beaverton, OR (US); Chun Wing Yeung, Portland, OR (US); Feng Zhang, Portland, OR (US); Chung-Hsun Lin, Portland, OR (US); Oleg Golonzka, Beaverton, OR (US); Marko Radosavljevic, Portland, OR (US); Anand Murthy, Portland, OR (US)

(73) Assignee: Intel Corporation, Santa Clara, CA (US)

(21) Appl. No.: 18/759,229

(22) Filed: Jun. 28, 2024

(51) Int. Cl. H01L 29/08; H01L 21/822; H01L 27/06; H01L 27/092; H01L 29/06; H01L 29/423; H01L 29/778; H01L 29/786

(52) U.S. Cl. CPC H10D 62/151; H10D 30/47; H10D 30/6735; H10D 30/6757; H10D 62/118; H10D 84/038; H10D 84/856; H10D 88/00; H10D 88/01

(57) ABSTRACT

Integrated circuit (IC) devices having stacked, complementary transistors with channels of different compositions. A device includes transistors with first and second groups of nanoribbons vertically aligned in a stack of nanoribbon channels coupling first and second sources and drains, and one of the first and second nanoribbons has a semiconductor element absent from the other. The first and second groups of nanoribbons extend between first and second spacers, which may have different compositions. First and second hardmasks with different compositions may be used process the first and second groups of nanoribbons separately. A masking layer having the composition of one of the first and second nanoribbons may mask the other of the first and second nanoribbons.

### BACKGROUND

Customer constraints and performance requirements provide continuous and increasing pressure to scale down integrated circuit (IC) devices. Transistor devices must provide improved performance while occupying less lateral space in IC dies and wafers. Stacking field-effect transistors (FETs) may halve areas occupied by some metal-oxide-semiconductor (MOS) FETs. For example, complementary MOS (CMOS) devices may be formed in a reduced area by stacking complementary n- and p-type MOSFETs, one over the other, in a complementary FET (CFET) configuration. However, conventional processing flows may be unsuited to stacking complementary NMOS and PMOS FETs or to optimizing performance for new CFET configurations, and some new processing flows may add unnecessary complexities and costs to, or in place of, methods that have been proven and honed for fabricating high-performance NMOS and PMOS devices. Additionally, some materials may work better for either (but, e.g., not both) of NMOS and PMOS, and existing (for example, non-CFET) processing methods, though functional, may not allow for some implementations that would employ different materials optimized for each complementary type of FET.

New techniques, structures, and materials are needed to improve both performance and efficient die-area utilization, ideally while also leveraging established processes with existing infrastructure, minimized variation, and maximized reliability.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a cross-sectional profile view of an integrated circuit (IC) device having a stack of nanoribbons of different compositions and polarity in transistor structures, in accordance with some embodiments;

FIG. 2 is a flow chart of methods for forming transistors with vertically aligned nanoribbon channels having different compositions, in accordance with some embodiments;

FIGS. 3A, 3B, 3C, 3D, 3E, 3F, 3G, 3H, 3I, 3J, 3K, 3L, 3M, 3N, 3O, and 3P illustrate cross-sectional profile views of a workpiece or device having a stack of alternating material layers, at various stages of manufacture, in accordance with some embodiments;

FIGS. 4A, 4B, 4C, 4D, 4E, 4F, 4G, 4H, 4I, 4J, 4K, 4L, 4M, 4N, 4O, and 4P illustrate cross-sectional profile views of a workpiece or device having a stack of alternating material layers, at various stages of manufacture, in accordance with some embodiments;

FIG. 5 illustrates a diagram of an example data server machine employing an IC device having vertically aligned nanoribbon channels of different compositions, in accordance with some embodiments; and

FIG. 6 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve integrated circuit (IC) devices having stacked metal-oxide semiconductor (MOS) transistors, such as field-effect transistors (FETs) in a complementary FET (CFET) configuration, for example, by the use of novel processing to segregate portions of a stack of channel structures and of optimized materials for each of the segregated portions.

The present disclosure describes stacked gate-all-around (GAA) FETs employing different materials in upper and lower stacks. The stacking conserves device area, and the vertical separation allows for partitioning of the upper and lower portions during processing. A lower GAA FET may have different channel materials and spacer materials than an upper GAA FET stacked over the lower GAA FET. For example, n- and p-type MOSFETs may be stacked one over the other in a CFET configuration, with channel materials optimized for each particular conductivity type. Typical structures use a same channel material in upper and lower stacks, e.g., in nanoribbons in GAA FETs, but the present disclosure enables the utilization of materials directed to a particular application, for example, in a complementary MOS (CMOS) device with silicon for NMOS and silicon germanium for PMOS transistors. In many embodiments, a CFET device includes a GAA PMOS FET with silicon germanium nanoribbons vertically aligned in a stack with a GAA NMOS FET with predominantly silicon nanoribbons. The use of silicon germanium nanoribbons in a PMOS channel enables lower threshold voltage VT, lower density of interface traps on channel surfaces, better device physics (e.g., mobility), and better reliability. Distinct spacer materials may be deployed around the separate, optimized channel materials on both sides of one or more gate electrodes, which may provide etch selectivities between the upper and lower stacks.

The present disclosure also describes novel processing techniques to take advantage of existing infrastructure and flows, but to segregate complementary device portions separately when necessary and to fabricate device portions concurrently when possible or convenient. For example, pairs of different mask materials may be used to enable the separate processing of complementary channel materials, and the complementary channel materials may be used as intervening sacrificial materials between channels in the complementary device portion. In some exemplary embodiments, a carbon hardmask covers a first device portion during processing of a second device portion, and a metal-based hardmask covers the second device portion while processing the first device portion. In many embodiments, one of the first or second device portions has channels of silicon and uses an alloy of silicon and germanium as a sacrificial material between channel layers, and the other of the first or second device portions has channels of silicon germanium and uses silicon as a sacrificial material between channel layers. A thin sacrificial layer of silicon may be used to mask a channel material (e.g., of Si_{1-X}Ge_{X}) having an etch selectivity with pure silicon.

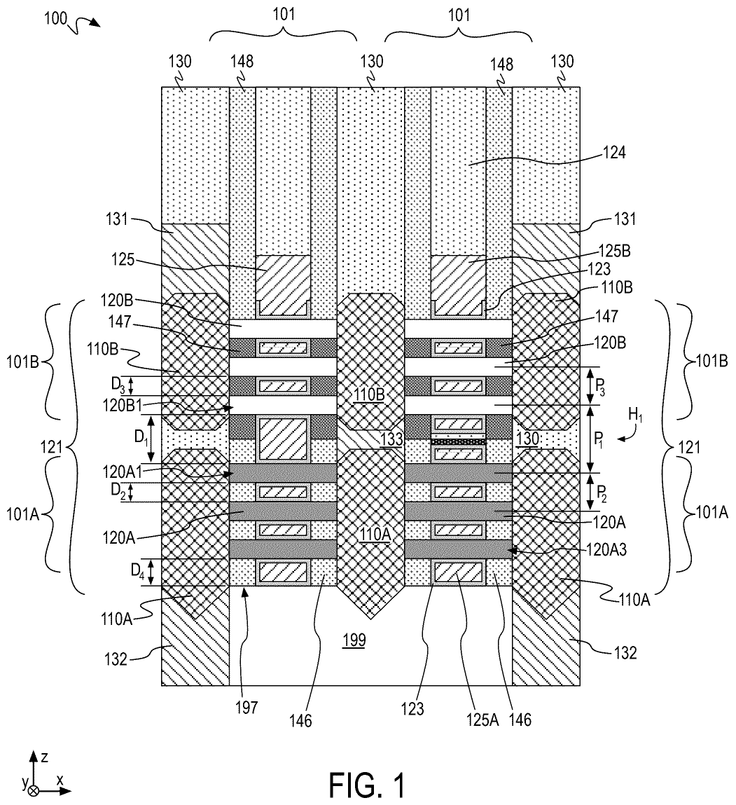

FIG. 1 illustrates a cross-sectional profile view of an IC device 100 having a stack 121 of nanoribbons 120A, 120B of different compositions and polarity in transistor structures 101, in accordance with some embodiments. Nanoribbons 120 are channel structures in transistor structures 101. In the example of FIG. 1, nanoribbons 120A, 120B are in complementary transistor structures 101A, 101B and are of materials having different electron and hole mobilities.

IC device 100 includes NMOS and PMOS transistor structures 101 over substrate 199. Device 100 includes a stack 121 of nanoribbons 120 (e.g., vertically aligned first and second nanoribbons 120A, 120B). Multiple nanoribbons 120A are in stack 121, between and coupling first source and drain bodies 110A. Multiple nanoribbons 120B are in stack 121, between and coupling first source and drain bodies 110B. In the example of FIG. 1, device 100 includes multiple, adjacent stacks 121 having complementary transistor structures 101 (e.g., NMOS and PMOS FETs) stacked over each other, with an upper group of nanoribbons 120B vertically aligned over a lower group of nanoribbons 120A.

In the example of FIG. 1, nanoribbons 120A, 120B include complementary channel materials. The channel materials are referred to herein as “complementary” because one channel material is advantageous for an NMOS transistor structure 101 while the other channel material is advantageous for a PMOS transistor structure 101. In exemplary embodiments, channel material within an NMOS transistor structure 101 offers higher electron mobility than the channel material within a PMOS structure 101. In exemplary embodiments, channel material within a PMOS transistor structure 101 likewise offers higher hole mobility than the channel material within a NMOS transistor structure 101. The high complementary carrier mobilities may therefore enable high drive currents independently for both NMOS and PMOS structures 101. NMOS and PMOS transistor structures 101 may be vertically stacked with either NMOS or PMOS structure 101 above or below the other. For clarity of discussion, nanoribbons 120B are referred to as being within a channel of NMOS transistor structure 101B while nanoribbons 120A are within a channel of PMOS transistor structure 101A.

In accordance with some embodiments, PMOS and NMOS nanoribbons 120A, 120B have complementary chemical compositions where one composition is advantageous for a p-type transistor and the other composition is advantageous for an n-type transistor. For example, nanoribbons 120A may each be a first Group IV, Group III-V, metal oxide, or metal chalcogenide semiconductor material while nanoribbons 120B are each a second Group IV, Group III-V, metal oxide, or metal chalcogenide semiconductor material. In many embodiments, one of first and second nanoribbons 120A, 120B includes a semiconductor element absent from the other of first and second nanoribbons 120A, 120B. In some notable Group IV embodiments, nanoribbons 120A include germanium (e.g., Si_{1-X}Ge_{X}, Ge_{1-X}Sn_{X}, or substantially pure Ge) while nanoribbons 120B include primarily silicon and may be substantially (pure) silicon (e.g., with germanium absent in nanoribbons 120B).

In some alternative Group III-V embodiments, nanoribbons 120A include a III-V material offering higher hole mobility, or may include a Group IV material (e.g., substantially pure Ge) having higher hole mobility. For such embodiments, nanoribbons 120B may further include another III-V material offering higher electron mobility, such as InGaAs, or InAs, for example. In other embodiments, nanoribbons 120A, 120B include a transition metal and a chalcogen. The chalcogen may be sulfur, selenium, and tellurium (e.g., MS_{X}, MSe_{X}, or MTe_{X}). The transition metal may be any transition metal such as any element of groups 4 through 11, the group 3 elements scandium and yttrium, and the inner transition metals (e.g., f-block lanthanide and actinide series). Advantageous transition metals for nanoribbons 120B within NMOS structure 101B include molybdenum and tungsten while advantageous transition metals for channel nanoribbons 120A within PMOS structure 101A include copper and indium. In still other embodiments, nanoribbons 120B include one or more first metals and oxygen (i.e., first metal oxide semiconductor), such as indium gallium zinc oxide (e.g., InGaZnO_{X} or simply “IGZO”) while nanoribbons 120A include one or more second metals and oxygen (i.e., a second metal oxide semiconductor), such as CuO_{X}.

As further illustrated in FIG. 1, NMOS nanoribbons 120B are coupled to, and in contact with, n-type source and drain bodies 110B. Source and drain bodies 110B may have any chemical composition and microstructure suitable for an NMOS transistor. N-type source and drain bodies 110B may include monocrystalline or polycrystalline semiconductor material. In many embodiments, n-type source and drain bodies 110B include a Group IV or III-V semiconductor material doped with any impurity dopants known to be suitable for the desired conductivity type, and to any concentration known to be suitable for transistors. In some embodiments, bodies 110B include silicon and an n-type dopant, such as phosphorous, arsenic, or another donor impurity.

PMOS nanoribbons 120A are coupled to, and in contact with, p-type source and drain bodies 110A. Source and drain bodies 110A are in a vertical (e.g., along z-axis) stack with n-type source and drain bodies 110B. Space between n-type source and drain bodies 110B and p-type source and drain bodies 110A may be filled with any suitable insulator 130. Insulator 130 may be SiO₂ or a low-permittivity (“low-K”) dielectric material (e.g., SiOCH), for example. P-type source and drain bodies 110A may have any chemical composition and microstructure suitable for a PMOS transistor. Source and drain bodies 110A may include monocrystalline or polycrystalline semiconductor material. In many embodiments, source and drain bodies 110A include a Group IV or III-V semiconductor material doped with any impurity dopants known to be suitable for the desired conductivity type, and to any concentration known to be suitable for transistors. In some embodiments, bodies 110A include silicon, germanium, and a p-type dopant, such as boron, aluminum, gallium or any other acceptor impurity. In some exemplary embodiments, source and drain bodies 110B are predominantly silicon doped with any suitable concentration of donor impurities while source and drain bodies 110A are predominantly silicon germanium doped with any suitable concentration of acceptor impurities.

Stack 121 of first and second nanoribbons 120A, 120B includes a first pitch P₁ between an uppermost of first nanoribbons 120A (e.g., nanoribbon 120A1) and a lowermost of second nanoribbons 120B (e.g., nanoribbon 120B1). Second pitch P₂ is between first nanoribbons 120A in the lower group of nanoribbons 120 (e.g., first nanoribbons 120A), and third pitch P₃ is between second nanoribbons 120B in the upper group of nanoribbons 120 (e.g., second nanoribbons 120B). In many embodiments, second and third pitches P₂, P₃ are equal. In some embodiments, first pitch P₁ is at least one-and-a-half times each of second and third pitches P₂, P₃ between first nanoribbons 120A. The ratio of pitches P₁:P₂ (or pitches P₁:P₃) may provide sufficient separation between nanoribbons 120A, 120B (and structures 101A, 101B), for example, during processing or device operation.

Individual ones of the lower group of nanoribbons 120 (e.g., nanoribbons 120A) are separated by distance D₂, and individual ones of the upper group of nanoribbons 120 (e.g., second nanoribbons 120B) are separated by distance D₃. In many embodiments, distances D₂, D₃ are equal. An uppermost of first nanoribbons 120A (e.g., nanoribbon 120A1) and a lowermost of second nanoribbons 120B (e.g., nanoribbon 120B1) are separated by a distance D₁. Distance D₁ is at least twice distance D₂. Distance D₁ is at least twice distance D₃. The ratio of distances D₁:D₂ (or distances D₁:D₃) may provide sufficient separation between nanoribbons 120A, 120B (and structures 101A, 101B), for example, during processing or device operation.

Stack 121 of first and second nanoribbons 120A, 120B is over substrate 199. An uppermost surface 197 of substrate 199 and a lowermost of first nanoribbons 120A (e.g., nanoribbon 120A3) are separated by fourth distance D₄. Fourth distance D₄ is at least one-and-a-half times distance D₂ between nanoribbons 120A, which may provide sufficient space for a gate electrode 125 under a lowermost of first nanoribbons 120A (e.g., nanoribbon 120A3).

IC device 100 and transistor structure 101 include gate electrode 125 between source and drain bodies 110A and between source and drain bodies 110B. Both nanoribbons 120A, 120B extend through gate electrode 125. Device 100 includes first spacer insulators 146 between source and drain bodies 110A and second spacer insulators 147 between source and drain bodies 110B. Gate electrode 125 is between spacer insulators 146, between spacer insulators 147, and between spacer insulators 147. Spacer insulators 148 are between bodies 110B, between metallization structures 131 and gate isolation 124, and between insulator 130 and gate isolation 124. Spacer insulators 148 are on insulators 147, over insulators 146, 147. Nanoribbons 120A extend through insulators 146. Nanoribbons 120B extend through insulators 147.

Spacer insulators 146, 147, 148 may have any suitable composition, for example, any suitably insulative (e.g., electrically insulative) composition. Advantageously, insulators 146, 147, 148 include one or more low-K materials. In many embodiments, one or both of insulators 146, 147, 148 include an oxide, nitride, and/or oxynitride. In some such embodiments, one or more of insulators 146, 147, 148 include an oxide and/or nitride doped with carbon. Spacer insulators 146, 147, 148 may include different materials in, for example, distinct layers. Different materials in insulators 146, 147, 148 may perform different functions, such as providing etch selectivities. In many embodiments, one or more of insulators 146, 147, 148 include an oxide and/or nitride, etc., of silicon (such as, but not limited to, SiN, SiO, SiON, SiOC, SiCN). In some embodiments, one or more of insulators 146, 147, 148 include an oxide and/or nitride, as well as hydrogen (e.g., SiOCH), which may correspond to a reduced permittivity. In some embodiments, one or more of insulators 146, 147, 148 include pores (e.g., nanopores) in an oxide and/or nitride, which may correspond to a reduced permittivity.

In some embodiments, insulators 146, 147, 148 have a same composition. In the example of FIG. 1, insulators 146 have a composition different than a composition of insulators 147, which may have a significant effect on a material characteristic (such etch selectivity or permittivity). In some embodiments, the compositional difference between insulators 146, 147 is that only one of insulators 146, 147 includes carbon, e.g., as a dopant. In some embodiments, the compositional difference between insulators 146, 147 is that one of insulators 146, 147 has an atomic composition of at least five percent more silicon, oxygen, or nitrogen. For example, one of insulators 146, 147 has an atomic composition of approximately fifty percent silicon, fifty percent oxygen, and no nitrogen, and the other of insulators 146, 147 has an atomic composition of at least fifty percent silicon and less than forty-five percent oxygen. The different compositions of spacer insulators 146, 147 may enable, for example, etch selectivities between insulators 146, 147, which may provide processing flexibilities, etc. Different compositions of spacer insulators 146, 147 may also enable the deployment of insulators 146, 147 optimized for particular applications, e.g., low-K dielectrics where necessary and spacer insulators with etch resistance where necessary. Spacer insulators 148 may have a same composition as one, both, or neither of insulators 146, 147.

One or more gate electrodes 125 are between individual ones of nanoribbons 120. Gate electrode 125 may include one or more insulator materials in a gate layer 123. In some embodiments, transistor structures 101A, 101B have distinct gate electrodes 125A, 125B. In some embodiments, transistor structures 101A, 101B share a common gate electrode 125. In some embodiments, one gate electrode 125B is between individual ones of nanoribbons 120B. Gate electrode 125B may include one or more gate insulator materials and one or more gate electrode materials (e.g., workfunction metals) advantageous for NMOS structure 101B. Another gate electrode 125A is between individual ones of nanoribbons 120A. Gate electrode 125A may include one or more gate insulator materials and one or more gate electrode materials advantageous for PMOS structure 101A. In some embodiments, gate electrode 125B includes a first high-K (“high-permittivity”) dielectric or ferroelectric material advantageous for n-type transistor structures 101B and a first workfunction metal advantageous for n-type transistor structures 101B while gate electrode 125A includes a second high-K dielectric or ferroelectric material advantageous for p-type transistor structures 101A and a second workfunction metal advantageous for p-type transistor structures 101A.

Exemplary high-K dielectrics (e.g., in gate layer 123) include metal oxides (e.g., including one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate), or metal silicates (e.g., including one or more of above metals, oxygen and silicon). Examples of work function metals (e.g., in gate electrode 125) include ruthenium, palladium, platinum, cobalt, nickel, and conductive metal oxides (e.g., ruthenium oxide), hafnium, zirconium, titanium, tantalum, aluminum, alloys of these metals, and carbides of these metals such as hafnium carbide, zirconium carbide, titanium carbide, tantalum carbide, and aluminum carbide.

Gate isolation 124 is over gate electrode 125. Isolation 124 may include a low-K dielectric material (such as those described of insulators 146, 147) that separates gate electrode 125 from interconnect metallization layers (e.g., in one or more interconnect networks), over and/or under structures 101. Trench insulator 130 is over source and drain bodies 110. Insulator 130 may include a low-K dielectric material that separates bodies 110 from interconnect metallization layers (e.g., in one or more interconnect networks), over and/or under structures 101. Isolation 124 and insulator 130 may have the same or differing compositions.

Transistor structures 101 may be coupled to interconnect metallization layers by (e.g., in one or more interconnect networks) by front- or back-side metallization structures 131, 132, which are contact structures on source and drain bodies 110. Structures 131, 132 may be coupled to interconnect metallization layers by vias through trench insulator 130. Gate electrode 125 may be coupled to interconnect metallization layers by vias through gate isolation 124. Transistor structures 101 may be coupled at source and drain bodies 110 by mid-stack metallization structures 133. In some embodiments, transistor structures 101 are isolated between source and drain bodies 110 by trench insulator 130.

Substrate 199 may include any suitable material or materials. Any suitable semiconductor or other material can be used. Substrate 199 may be any suitable substrate 199, such as a wafer, die, etc. Substrate 199 may include a semiconductor material that transistors can be formed out of and on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, substrate 199 includes crystalline silicon and subsequent components are also silicon. In some embodiments, a crystalline material of substrate 199 is removed (e.g., by grinding) from a back-side of transistor structures 101 and replaced with an isolation material (e.g., like those of insulators 130, 146, 147; isolation 124; etc.). Substrate 199 may be a silicon-on-insulator (SOI) substrate. Substrate 199 may also include semiconductor materials, metals, dielectrics, dopants, and other materials commonly found in IC substrates.

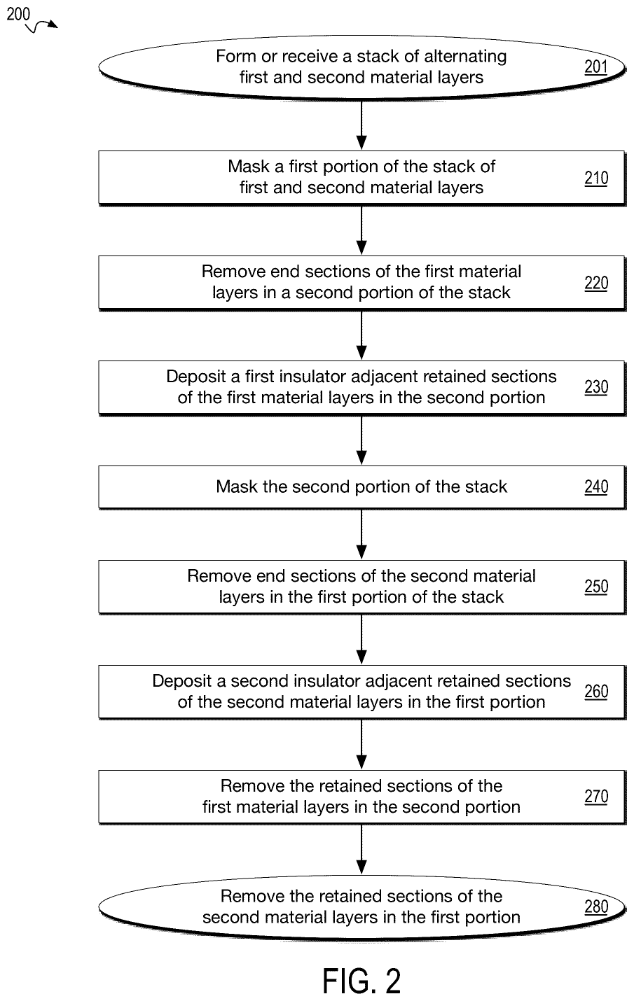

FIG. 2 is a flow chart of methods 200 for forming transistors with vertically aligned nanoribbon channels having different compositions, in accordance with some embodiments. Methods 200 include operations 201-280. Some operations shown in FIG. 2 are optional. Additional operations may be included. FIG. 2 shows an example sequence, but the operations can be done in other orders as well, and some operations may be omitted. Some operations can also be performed multiple times before other operations are performed. For example, either or both of the first and second portions of the stack of layers may be masked multiple times as is necessary or convenient for performing various other operations. Some operations may be included within other operations so that the number of operations illustrated FIG. 2 is not a limitation of the methods 200.

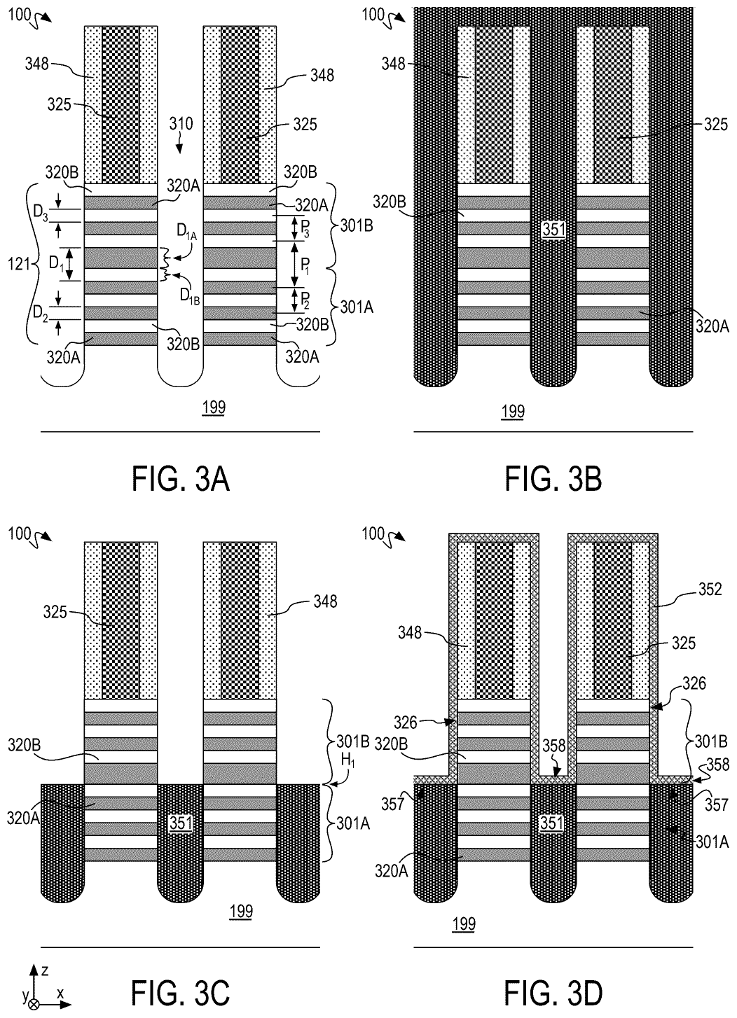

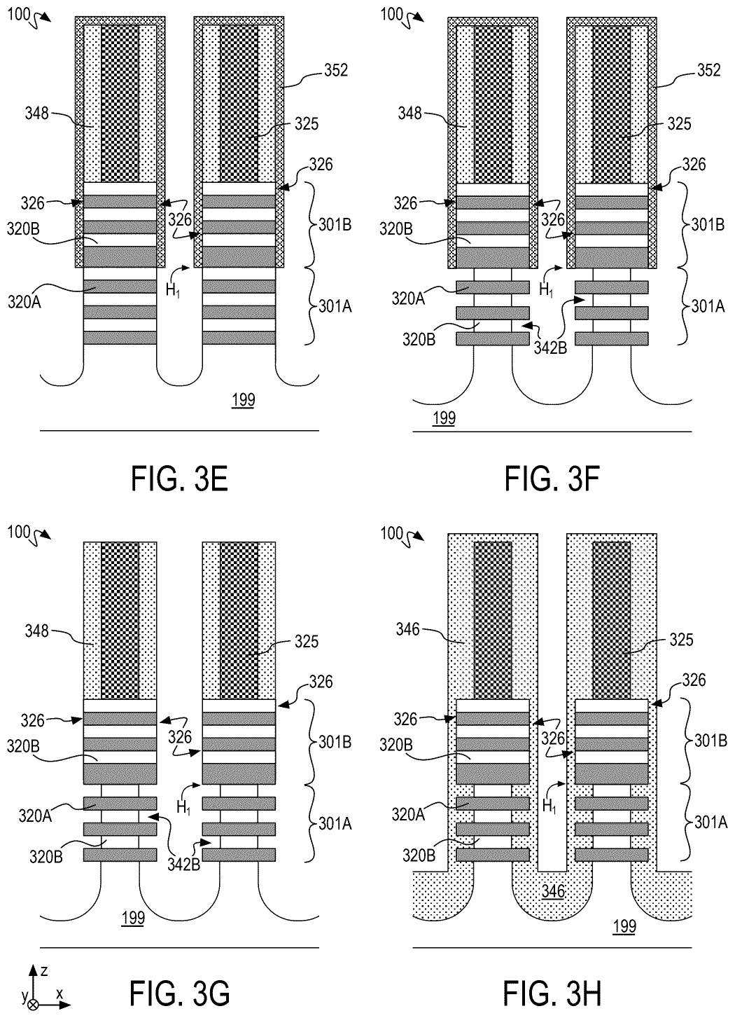

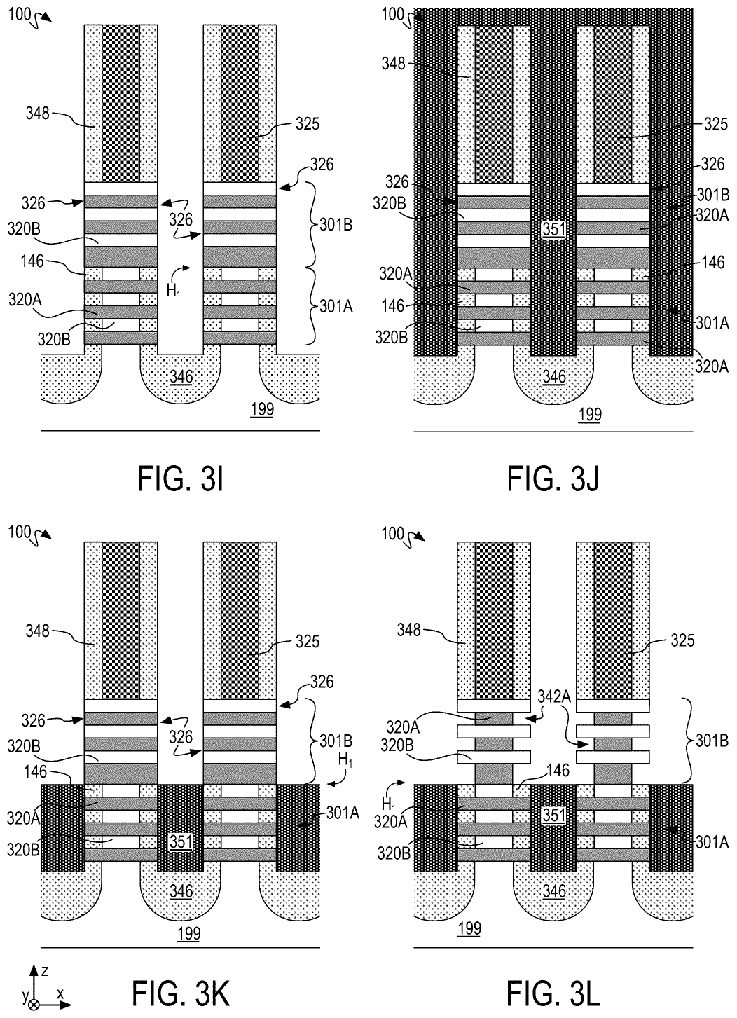

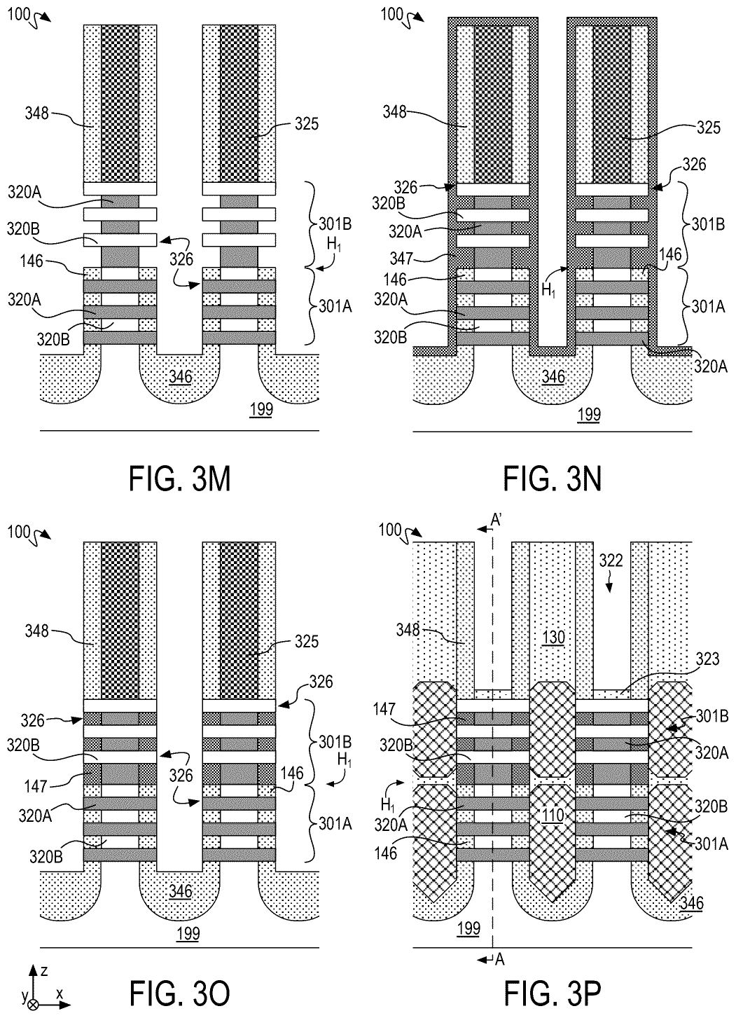

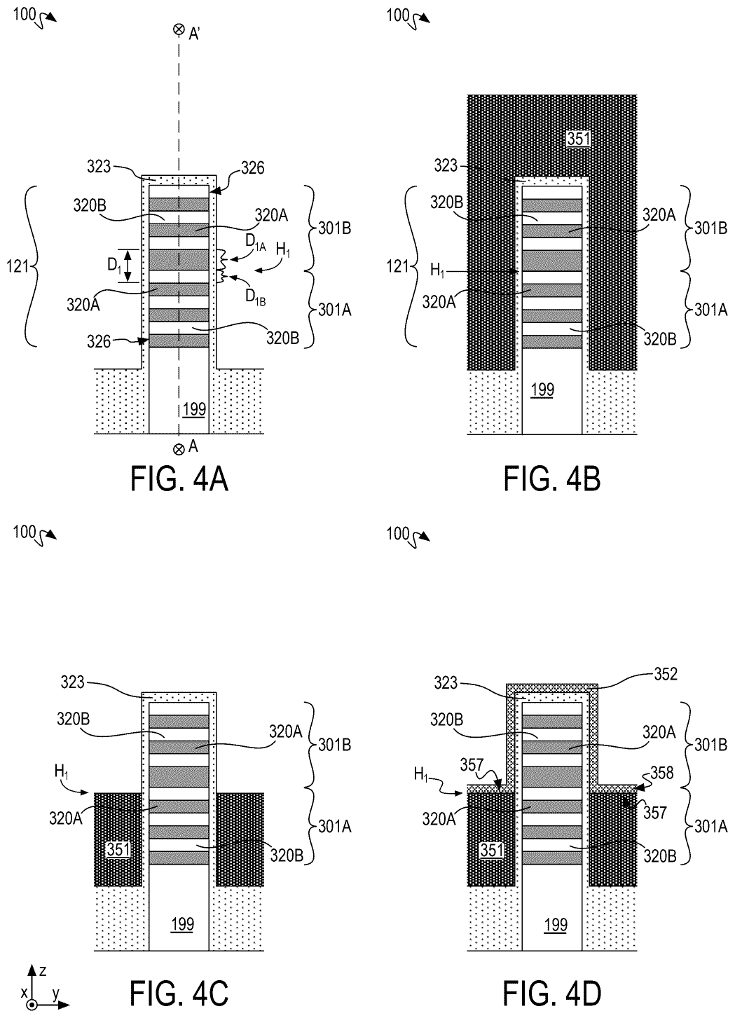

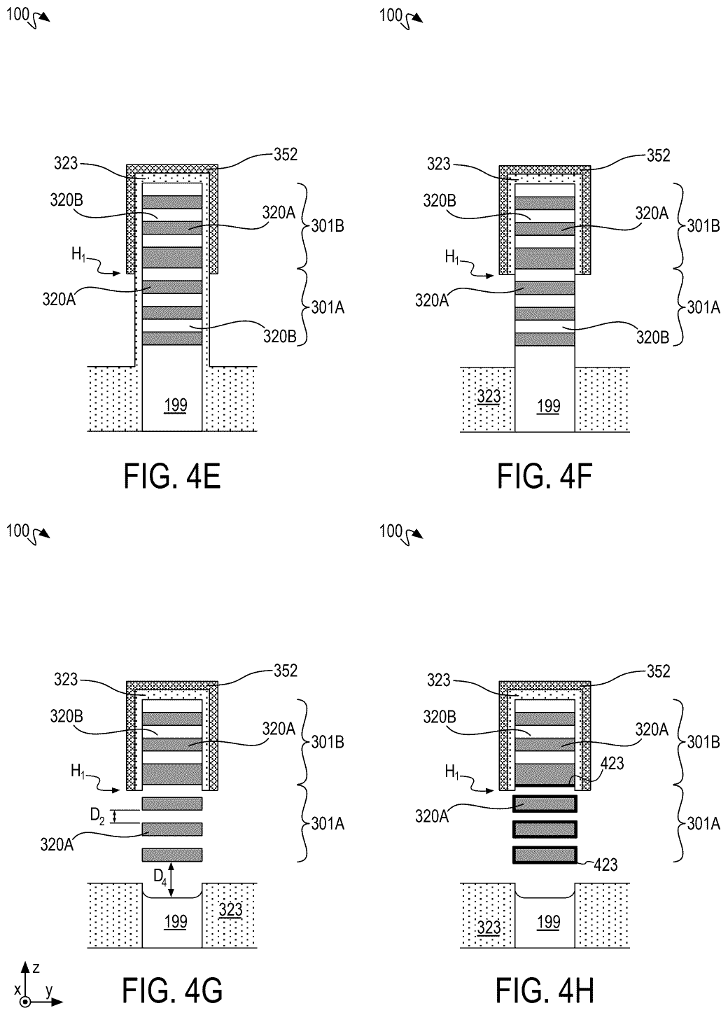

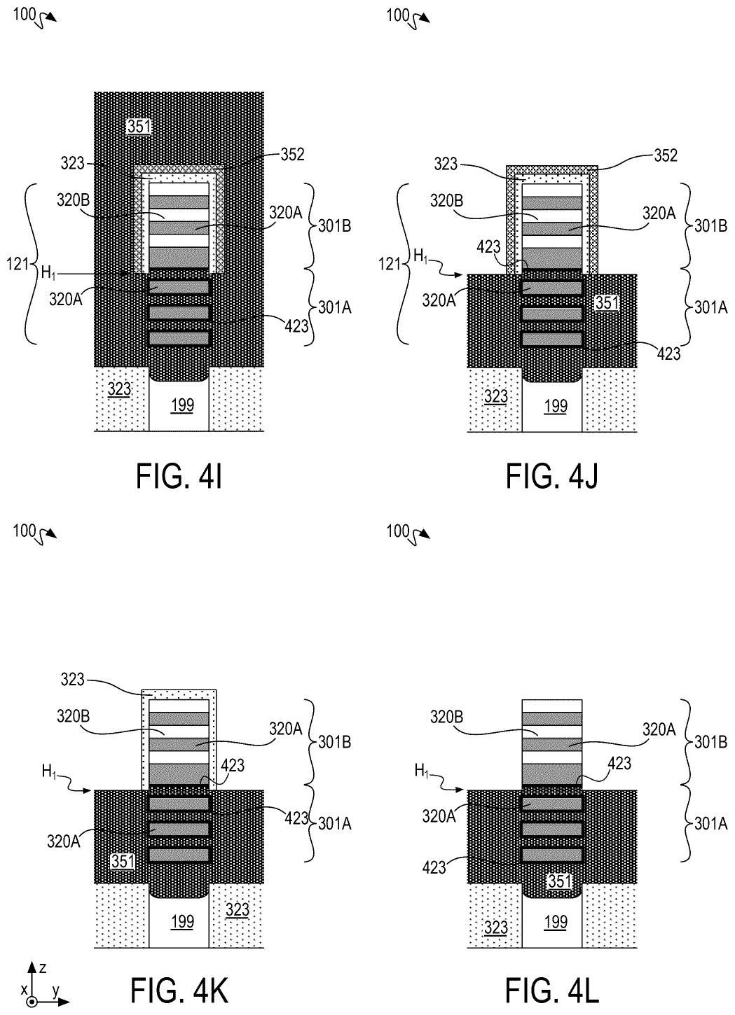

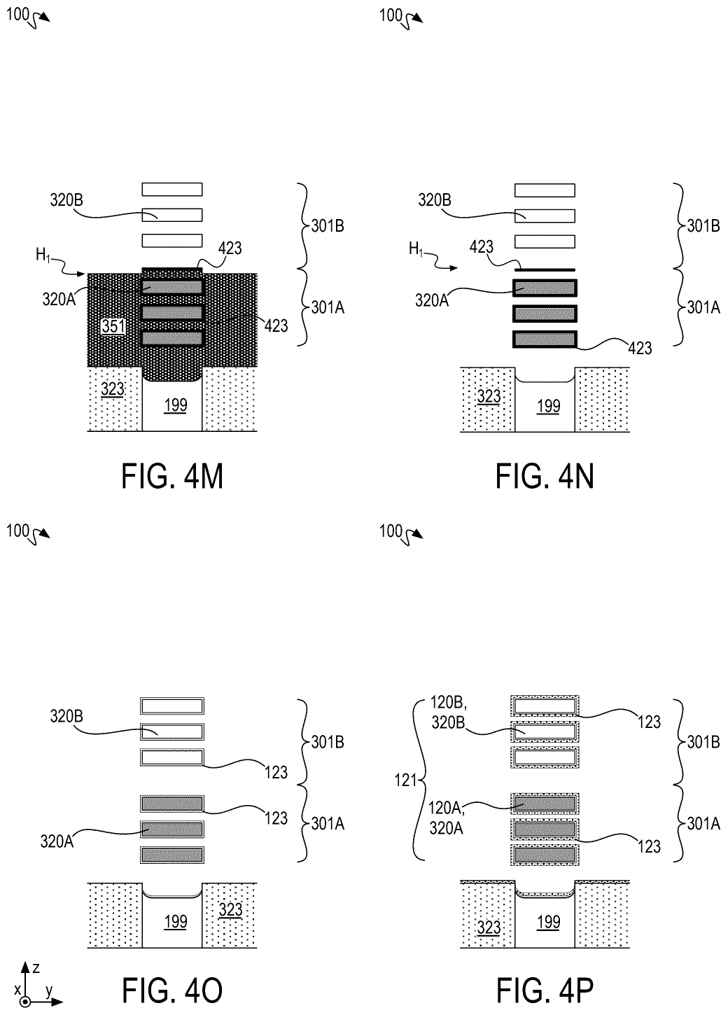

FIGS. 3A, 3B, 3C, 3D, 3E, 3F, 3G, 3H, 3I, 3J, 3K, 3L, 3M, 3N, 3O, and 3P illustrate cross-sectional profile views of a workpiece or device having a stack of alternating material layers, at various stages of manufacture, in accordance with some embodiments. For example, FIGS. 3A-3P show possible examples of intermediate structures during an embodiment of a practice of methods 200 of FIG. 2, e.g., masking and recess etching of portions of the material stack. For illustrative purposes, FIGS. 3A-3P utilize an x-z viewing plane, e.g., to show dimple etching between channel material layers. FIG. 3P shows the orientation of the y-z viewing plane A-A′ of FIGS. 4A-4P.

FIGS. 4A, 4B, 4C, 4D, 4E, 4F, 4G, 4H, 4I, 4J, 4K, 4L, 4M, 4N, 4O, and 4P illustrate cross-sectional profile views of a workpiece or device having a stack of alternating material layers, at various stages of manufacture, in accordance with some embodiments. For example, FIGS. 4A-4P show possible examples of intermediate structures during an embodiment of a practice of methods 200 of FIG. 2, e.g., masking portions of the material stack and releasing channel material layers. For illustrative purposes, FIGS. 4A-4P utilize a y-z viewing plane, e.g., to show mask materials to either side of channel material layers (e.g., in the y-directions).

Returning to FIG. 2, methods 200 begin at operation 201 with receiving or forming a stack of alternating first and second material layers. Methods 200 allow for the processing of stacks (e.g., as received) of new or conventional material layers. The stack may include material layers capable of serving as a channel material in either or both of n- and p-type transistors. The first and second material layers may advantageously have etch selectivities suitable for serving as sacrificial material, e.g., between the other material layers in a complementary portion of the stack.

In many embodiments, the stack of alternating first and second material layers is formed at operation 201. In many such embodiments, forming the stack of alternating first and second material layers includes alternately depositing first (or second) material layers of silicon and second (or first) material layers of silicon and germanium. (Either of the first and second material layers may be formed first, second, etc., e.g., in any order. For example, first material layers may be formed before some second material layers and after other second material layers, and some second material layers may be formed before some first material layers and after other first material layers.) In many embodiments, forming the stack includes alternately depositing the first and second material layers in one (e.g., a lower) portion of the stack before alternately depositing the first and second material layers in another portion of the stack (e.g., an upper portion of the stack, over the lower portion of the stack). As initially formed, the (e.g., upper and lower) portions may be substantially similar to each other. After further processing, in one portion, the first material layers may become the channel layers (and the second material layers the sacrificial layers), and the second material layers may become the channel layers (and the first material layers the sacrificial layers) in the other portion.

The stack may be formed by any suitable means, e.g., by alternating atomic layer depositions (ALD) of each layer. For example, a first material layer may be epitaxially deposited over a crystalline substrate, a second material layer may be epitaxially deposited over the first material layer, and that process may be repeated as necessary to form a stack of alternating first and second material layers over a substrate. The material layers may be formed to any suitable thickness(es), e.g., for channel material layers to have an appropriate thickness and for sacrificial material layers to provide appropriate vertical spacing between channel material layers. In some embodiments, the first and/or second material layers have a same thickness in upper and lower portions. In some embodiments, the first material layers have different thicknesses in upper and lower portions. In some embodiments, the second material layers have different thicknesses in upper and lower portions.

In some embodiments, forming the stack includes depositing an uppermost first or second material layer of the lower portion of the stack or a lowermost first or second material layer of the upper portion of the stack to a first thickness greater than a second thickness of an example (e.g., a lowermost) of the first or second material layers of the lower portion of the stack. Forming the stack with a greater thickness for either or both of these intervening layers may provide necessary separation between upper and lower portions of the stack, e.g., for processing operations performed on only one of the portions. Either or both of these layers (e.g., at the top of a lower portion or at the bottom of an upper portion) may be sacrificial layers between the to-be-retained channel layers of the upper and lower portions, and the thicknesses of the between-portions sacrificial layers may be used to set the pitch or distance between the (e.g., complementary) upper and lower portions. Either or both of these sacrificial layers may be formed to a greater (e.g., thicker) or lesser (e.g., thinner) thickness to set the appropriate spacing between upper and lower portions of the stack. Although examples (e.g., FIG. 3A) may describe embodiments with two intervening layers between upper and lower portions, other quantities of layers may be employed.

The material-layer stack may be patterned into parallel fins extending in a first dimension, for example, according to any lithographic patterning process. For exemplary embodiments, fin lines may extend any length along a first dimension and have a width in a second, orthogonal dimension. Any lithographic masking process and material etch process(es) may be utilized. The fin lines may be further etched into fin segments with each fin segment defining a transistor channel material stack. This further etching may be with a second lithographic patterning process defining lines/trenches that are substantially orthogonal to the fin lines, for example.

FIG. 3A illustrates stack 121 of sacrificial and channel material layers 320 in workpiece or device 100, in accordance with some embodiments, for example, following a performance of forming or receiving operation 201. Layers 320 are in portions 301 of stack 121 over substrate 199. Opening 310 is between stacks 121 of layers 320. Dummy gate 325 is over stack 121, between dummy gate spacers 348.

Dummy gate 325 and spacers 348 may serve as mask materials, e.g., for the etching of material layers 320 into segments. For example, dummy gates 325 may extend in the y-directions, over fins (e.g., of stacks 121 of layers 320) extending longitudinally in the x-directions. Etches through fins of stacks 121 and layers 320 may be directed between dummy gates 325 and spacers 348, which mask covered portions of stacks 121 and layers 320.

Layers 320A may be retained as channel material layers 320A in portion 301A of stack 121 and may serve as sacrificial material layers 320A in portion 301B of stack 121. Layers 320B may be retained as channel material layers 320B in stack portion 301B and may serve as sacrificial material layers 320B in stack portion 301A. Layers 320B may be of a same material as substrate 199. In many embodiments, channel material layers 320A are predominantly silicon (e.g., pure silicon), for example, for deployment in an NMOS transistor structure, and channel material layers 320B are silicon germanium, for example, for deployment in a PMOS transistor structure. In some embodiments, NMOS channel layers 320A are in lower portion 301B, and PMOS channel layers 320B are in upper portion 301A.

Channel material layers 320A in stack portion 301A have a pitch P₂ between layers 320A and are each separated by distance D₂. Channel material layers 320B in stack portion 301B have a pitch P₃ between layers 320B and are each separated by distance D₃. Distance D₁ separates an uppermost of channel material layers 320A in stack portion 301A from a lowermost of channel material layers 320B in stack portion 301B. Distance D₁ is made up of a thickness or distance D_{1A} of a lowermost of sacrificial material layers 320A in stack portion 301B and a thickness or distance D_{1B} of an uppermost of sacrificial material layers 320B in stack portion 301A. Pitch P₁ is between an uppermost of channel material layers 320A in stack portion 301A and a lowermost of channel material layers 320B in stack portion 301B.

Returning to FIG. 2, methods 200 continue with masking a first portion of the stack at operation 210. The first portion to be masked may be vertically aligned with (e.g., above or below) a second portion of the stack. The first portion may be masked by any suitable means and using any suitable material(s), e.g., any means and/or material(s) that provides a satisfactory etch selectivity with exposed materials in the non-masked second portion. In many embodiments (e.g., having the second portion vertically aligned over the first portion), the masking the first portion of the stack includes depositing a mask material to a level adjacent an uppermost first or second material layer of the first portion and a lowermost first or second material layer of the second portion (e.g., to a level between first and second portions). Depositing a mask material to a certain level may be by any suitable means, e.g., by a blanket deposition (e.g., over an entirety of a substrate). In some embodiments, the masking the first portion of the stack includes recessing a deposited mask material to a level adjacent an uppermost first or second material layer of the first portion and a lowermost first or second material layer of the second portion. The deposited mask material may be recessed (or fully removed) by any suitable means, such as a selective dry etch. In many embodiments, the mask material adjacent the first (e.g., lower) portion is a hardmask material, for example, that provides an etch selectivity with adjacent, exposed structures, such as silicon-based structures. In some such embodiments, the hardmask material includes carbon, e.g., amorphous carbon. In addition to providing an etch selectivity with adjacent silicon-based structures, carbon hardmasks may enable fine recess or depth control of the mask material. Other, e.g., metal-based, hardmask materials may be deployed.

In many embodiments (e.g., having a to-be-masked, first portion vertically aligned over a second portion to be left exposed), the masking the first portion of the stack includes depositing and recessing a first mask material to a level adjacent an uppermost first or second material layer of the second portion and a lowermost first or second material layer of the first portion, depositing a second mask material over the first mask material and the first portion, and removing the first mask material. In many embodiments, the mask material adjacent an upper first portion is a hardmask material (e.g., a metal or carbon hardmask material), for example, that provides an etch selectivity with adjacent, exposed structures, such as silicon-based structures. Other suitable mask material(s) may be deployed.

The deposition of the second mask material may be by any suitable means, e.g., by a conformal deposition over a substrate, including over the second portion and the first mask material (over the first portion). In some embodiments, the depositing the second mask material over the first mask material and the first portion includes a physical vapor deposition (PVD), e.g., a sputter, of the second mask material over a sidewall of the first portion and a lateral surface of the first mask material. In some such embodiments, the second mask material includes a metal (such as titanium, tantalum, etc.), for example, in a metal nitride. A PVD of a metal-nitride second mask material over a carbon first mask material may provide advantageously non-nucleated (e.g., spotty) growth, so when the carbon first mask material is removed (e.g., ashed away), the metal-nitride second mask material deposited over the lateral surface of the first mask material is removed with the carbon first mask material.

FIG. 3B shows a first mask material 351 adjacent (and in contact with) sacrificial and channel material layers 320 in workpiece or device 100, in accordance with some embodiments, for example, during a performance of masking operation 210. In many embodiments, as in the example of FIG. 3B, first mask material 351 is a carbon hardmask material blanket deposited over substrate 199. In some embodiments, first mask material 351 is deposited to a level between upper and lower portions of the stack of layers 320.

FIG. 3C illustrates mask material 351 at a level or height H₁ between portions 301A, 301B of sacrificial and channel material layers 320 in workpiece or device 100, in accordance with some embodiments, for example, following a performance of masking operation 210. In some embodiments, as in the example of FIG. 3B, first mask material 351 is recessed to a level between lower and upper portions 301A, 301B of the stack of layers 320.

FIG. 3D shows second mask material 352 on stack portion 301B and over first mask material 351 in workpiece or device 100, in accordance with some embodiments, for example, during a performance of masking operation 210. Second mask material 352 is conformally over and on a sidewall 326 of portion 301B and a lateral surface 357 of first mask material 351. A lateral portion 358 of second mask material 352 is on lateral surface 357 of first mask material 351. Material 352 is also conformally over and on dummy gate 325 and gate spacers 348.

FIG. 3E illustrates stack portion 301A unmasked and stack portion 301B masked by material 352 in workpiece or device 100, in accordance with some embodiments, for example, following a performance of masking operation 210. A first mask material is absent adjacent unmasked stack portion 301B. Second mask material 352 remains conformally over and on sidewall 326 of portion 301B, but a lateral portion of material 352 is absent. Second mask material 352 is over portion 301B (and dummy gate 325 and spacers 348) down to approximately level or height H₁ between portions 301A, 301B. The deposited first mask material may be removed by any suitable means, such as a selective dry etch.

Returning to FIG. 2, methods 200 continue with removing first end sections of the first material layers in the second portion at operation 220. The removal of end sections of the sacrificial first material layers in the second portion enables the formation of spacers, insulators between retained channel material layers and (eventually) between a gate electrode and source and drain bodies on both sides of the gate electrode. Any suitable means may be employed to remove the end sections, for example, by recessing the exposed sacrificial layers. The end sections of sacrificial layers in the non-masked second portion may be removed by a recess (or “dimple”) etch, e.g., an isotropic (wet or dry) etch of the exposed sacrificial layers that is selective to the channel material layers to be retained.

FIG. 3F shows recessed sacrificial material layers 320B in stack portion 301A in workpiece or device 100, in accordance with some embodiments, for example, following a performance of removing operation 220. Voids or cavities 342B are between end sections of channel layers 320A, e.g., where absent end sections of sacrificial layers 320B were prior to removal at operation 220. Second mask material 352 covers portion 301B of the stack of layers 320A, 320B, over exposed portion 301A.

In the example of FIG. 3F, the exposed second portion 301A is a lower portion 301A, but, in some embodiments, lower portion 301A is a first masked portion 301A, and portion 301B is exposed and recessed. In embodiments with an exposed lower portion 301A, as in the example of FIG. 3F, recessing sacrificial material layers 320B may also recess substrate 199. For example, material layers 320B may predominantly be silicon (e.g., between silicon germanium layers 320A), substrate 199 may be silicon, and a selective, isotropic recess etch of sacrificial layers 320B may also recess substrate 199.

FIG. 3G illustrates exposed portion 301B over recessed sacrificial material layers 320B in stack portion 301A in workpiece or device 100, in accordance with some embodiments, for example, following a removal of an upper, conformal mask over first portion 301B. Portion 301B (including sidewalls 326 of layers 320A, 320B) is exposed without a second mask material, now absent, conformally over portion 301B. Dummy gate 325 and spacers 348 are exposed without the conformal second mask. The second mask material may be removed by any suitable means, for example, by a dry, selective etch.

Returning to FIG. 2, methods 200 continue with depositing a first insulator adjacent retained sections of the first material layers in the second portion at operation 230. The first insulator may include any suitable material(s) and may be deposited by any suitable means. For example, suitable first insulator material(s) may be as described of spacer insulators 146, 147 (e.g., at FIG. 1).

The first insulator may be deposited in voids or cavities left in place of removed end sections of the first material layers in the second portion, e.g., adjacent and in contact with the retained first material sections in the second portion. The first insulator may be deposited between retained second material layers in the second portion, and the second material layers in the second portion may extend between or through the first insulator. In some embodiments, the first insulator is deposited over the layer stack (e.g., conformally, over both first and second portions, etc.), including the retained the second material layers. In some embodiments, the first insulator is recessed back, which may expose the first and second material layers (e.g., at layer ends).

FIG. 3H shows first insulator 346 over both of portions 301A, 301B (including on and covering sidewalls 326) and substrate 199 in workpiece or device 100, in accordance with some embodiments, for example, during a performance of depositing operation 230. In some embodiments, first insulator 346 includes a same material as dummy gate spacers, e.g., over portion 301B.

FIG. 3I illustrates first insulators 146 between channel layers 320A and adjacent retained sections of sacrificial layers 320B in portion 301A and over substrate 199 in workpiece or device 100, in accordance with some embodiments, for example, following a performance of depositing operation 230. Sidewalls 326 of layers 320A, 320B in portion 301B and of channel layers 320A in portion 301A are exposed.

Returning to FIG. 2, methods 200 continue with masking the second portion of the stack at operation 240. The second portion may be masked in a matter described at operation 201 for masking the first portion (e.g., in a manner complementary to the means employed for masking the first portion). For example, in embodiments where the first portion is an upper portion over a lower, second portion, the upper first portion may be masked by a conformal, metal-based hardmask, and the lower second portion may be masked by a blanketed, carbon-based hardmask. Any suitable means and materials may be used. In some embodiments, masking the second portion of the stack includes depositing and recessing a mask material to a level adjacent an uppermost first or second material layer of the second portion and a lowermost first or second material layer of the first portion. In some embodiments (e.g., with an upper second portion), masking the second portion of the stack includes masking the first portion before conformally masking the second portion and removing the first mask adjacent the first portion.

FIG. 3J shows mask material 351 adjacent (and in contact with) sacrificial and channel material layers 320A, 320B (and spacer insulators 146 and dummy gate spacers 348) in workpiece or device 100, in accordance with some embodiments, for example, during a performance of masking operation 240.

FIG. 3K illustrates mask material 351 adjacent (and in contact with) sacrificial and channel material layers 320 in portion 301A, up only to height H₁ between portions 301A, 301B in workpiece or device 100, in accordance with some embodiments, for example, following a performance of masking operation 240. Sidewalls 326 of layers 320A, 320B in portion 301B are exposed, unmasked above height H₁. In some embodiments, as in the example of FIG. 3K, mask material 351 is recessed to height H₁ between lower and upper portions 301A, 301B of the stack of layers 320.

Returning to FIG. 2, methods 200 continue at operation 250 with removing second end sections of the second material layers in the first portion. Any suitable means may be employed to remove the end sections, for example, by a selective dimple etch that recesses the exposed sacrificial layers and retains the adjacent channel layers. The removal of end sections of the sacrificial second material layers in the now-exposed first portion may be performed in much the same manner as the removal of end sections of the sacrificial first material layers in the now-masked second portion. The removal of end sections of the sacrificial second material layers in the first portion enables the formation of spacer insulators between channel layers and between an eventual gate electrode and source and drain bodies on both sides of the gate electrode.

FIG. 3L shows recessed sacrificial material layers 320A in stack portion 301B in workpiece or device 100, in accordance with some embodiments, for example, during a performance of removing operation 250. Voids or cavities 342A are between end sections of channel layers 320B, e.g., where absent end sections of sacrificial layers 320A were prior to removal at operation 250. Mask material 351 covers portion 301A of the stack of layers 320A, 320B, under exposed portion 301B.

FIG. 3M illustrates recessed sacrificial material layers 320A in stack portion 301B over unmasked and exposed portion 301A in workpiece or device 100, in accordance with some embodiments, for example, following a removal of a blanket mask over portion 301A. Portion 301A (including sidewalls 326 of layers 320A, 320B) is exposed without a mask material, now absent, adjacent portion 301A. The blanket-deposited mask material may be removed by any suitable means, such as a selective dry etch.

Returning to FIG. 2, methods 200 continue with depositing a second insulator adjacent retained sections of the second material layers in the first portion at operation 260. The second insulator may include any suitable material(s) and may be deposited by any suitable means, for example, much as the first insulator. In some embodiments, the second insulator has a same composition as the first insulator. The second insulator may be deposited in voids or cavities left in place of removed end sections of the second material layers in the first portion, e.g., adjacent and in contact with the retained second material sections in the first portion. The second insulator may be deposited between retained first material layers in the first portion, and the first material layers in the first portion may extend between or through the second insulator. In some embodiments, the second insulator is conformally deposited over both first and second portions of the layer stack, including the retained the first material layers. In some embodiments, the second insulator is recessed back, which may expose the first and second material layers (e.g., at layer ends).

In some embodiments, the second insulator is deposited with a composition different than the composition of the first insulator. Different compositions of first and second spacer insulators may enable, for example, etch selectivities between first and second insulators and first and second (e.g., upper and lower) stack portions, which may provide flexibility during performance of methods 200. Different compositions of spacer insulators may also enable the deployment of spacers optimized for particular applications, e.g., low-K dielectrics where necessary and spacer insulators with etch resistance where necessary. Compositions and compositional differences may be much as described at FIG. 1 (e.g., of spacer insulators 146, 147).

FIG. 3N shows second insulator 347 over both of portions 301A, 301B (including on and covering sidewalls 326), first insulators 146, and substrate 199 in workpiece or device 100, in accordance with some embodiments, for example, during a performance of depositing operation 260. In some embodiments, second insulator 347 includes a same material as first insulators 146 and/or dummy gate spacers 348.

FIG. 3O illustrates second insulators 147 between channel layers 320B and adjacent retained sections of sacrificial layers 320A in portion 301B in workpiece or device 100, in accordance with some embodiments, for example, following a performance of depositing operation 260. Sidewalls 326 of channel layers 320B in portion 301B and of channel layers 320A in portion 301A are exposed.

FIG. 3P shows channel layers 320A in portion 301A and channel layers 320B in portion 301B between and coupled with source and drain bodies 110 in workpiece or device 100, in accordance with some embodiments, for example, following a performance of operations 201-260 and prior to performance of operations 270-280 (e.g., as described at FIGS. 4A-4P). FIG. 3P shows the orientation of the y-z viewing plane A-A′ utilized in FIGS. 4A-4P for other operations.

Sacrificial layers 320B in portion 301A are between spacer insulators 146. Channel layers 320A in portion 301A extend between and through spacer insulators 146. Sacrificial layers 320A in portion 301B are between spacer insulators 147. Channel layers 320B in portion 301B extend between and through spacer insulators 147.

Void or opening 322 is between spacers 348 and trench insulators 130. No dummy gate is present between spacers 348. Trench insulator 130 is between spacers 348, adjacent source and drain bodies 110. A layer of dielectric 323 is on an uppermost channel layer 320B, between spacers 348. Dielectric 323 may be an oxide that provides isolation for channel layers 320A, 320B. Dielectric 323 may be a native oxide or passivation layer over the stack of layers 320. In many embodiments, dielectric 323 includes silicon.

In many embodiments, source and drain bodies 110 are formed, for example, epitaxially, from the exposed ends of channel layers 320A, 320B, e.g., following the formation of spacer insulators 146, 147. In many embodiments, opening 322 is formed by the removal of a dummy gate between spacer insulators 146, 147, e.g., following the formation of bodies 110 and trench insulator 130.

FIGS. 4A, 4B, 4C, 4D, 4E, 4F, 4G, 4H, 4I, 4J, 4K, 4L, 4M, 4N, 4O, and 4P illustrate cross-sectional profile views of workpiece or device having stack 121 of alternating material layers 320, at various stages of manufacture, in accordance with some embodiments, for example, following a performance of some or all of operations 201-260 of methods 200. For example, FIGS. 4A-4P show possible examples of intermediate structures during an embodiment of a practice of methods 200 of FIG. 2, e.g., releasing channel material layers. Portions of the material stack may be masked as necessary during a practice of methods 200, e.g., much as previously described at operations 210 and 240. For illustrative purposes, FIGS. 4A-4P are in a y-z viewing plane A-A′, e.g., to show mask materials to either side (e.g., in the y-directions) of channel material layers.

FIG. 4A illustrates stack 121 of sacrificial and channel material layers 320 in workpiece or device 100, in accordance with some embodiments, for example, following a performance of some or all of operations 201-260 of methods 200. Channel layers 320 may extend in both x-directions and couple source and drain bodies, as shown at FIG. 3P. Channel layers 320A in portion 301A and channel layers 320B in portion 301B extend between and through spacer insulators (not shown) in front of and behind the y-z viewing plane A-A′ (e.g., in both x-directions). Sacrificial layers 320B in portion 301A and sacrificial layers 320A in portion 301B are between spacer insulators (not shown) in front and behind the y-z viewing plane (e.g., in both x-directions). Though channel and sacrificial layers 320 may have the same or similar dimensions in the y-z viewing plane A-A′ of FIG. 4A, sacrificial layers 320A, 320B may extend less far (e.g., in both x-directions) than channel layers 320A, 320B.

A layer of dielectric 323 is over stack 121, on an uppermost channel layer 320B and on sidewalls 326 of layers 320. (Note that sidewalls 326 on dielectric 323 in FIG. 4A are orthogonal to sidewalls 326 described at, for example, FIG. 3O, which may be coupled to source and drain bodies.) Dielectric 323 may provide isolation for channel layers 320A, 320B and between stack 121 and adjacent stacks (not shown; e.g., in either or both y-directions). Stack 121 of layers 320 may be over substrate 199, which may be or include a subfin between trench isolations of dielectric 323.

Channel layers 320A, 320B in portions 301A, 301B are separated by distance D₁, a sum of thickness or distance D_{1A} (of a lowermost of sacrificial layers 320A in stack portion 301B) and thickness or distance D_{1B} (of an uppermost of sacrificial layers 320B in stack portion 301A). One or both of thicknesses or distances D_{1A}, D_{1B} may be greater than thicknesses of other layers 320, e.g., to provide a greater separation between portions 301A, 301B.

FIG. 4B shows mask material 351 on and over dielectric 323, over stack 121 of layers 320 in workpiece or device 100, in accordance with some embodiments, for example, during a performance of masking operation 210 or 240. Stack 121 may be masked much as previously described, e.g., at operation 210 or 240, for example, in preparation for releasing channel layers 320. In many embodiments, mask material 351 is a hardmask material 351, for example, including carbon.

FIG. 4C illustrates mask material 351 on dielectric 323 up to height H₁, adjacent portion 301A of stack 121 of layers 320 in workpiece or device 100, in accordance with some embodiments, for example, during a performance of masking operation 210 or 240. Dielectric 323 adjacent portion 301B is exposed over height H₁. In many embodiments, mask material 351 is recessed down to height H₁.

FIG. 4D shows mask material 352 on dielectric 323 over height H₁ (adjacent upper portion 301B of stack 121) and on mask material 351 below height H₁ (adjacent lower portion 301A), in accordance with some embodiments, for example, during a performance of masking operation 210 or 240. Mask material 352 is conformally over and on dielectric 323 and on lateral surface 357 of mask material 351. Lateral portion 358 of material 352 is on lateral surface 357 of material 351. In many embodiments, mask material 352 is a metal-based hardmask material 352, for example, including titanium or tantalum. In some such embodiments, mask material 352 includes nitrogen. In some embodiments, metal hardmask material 352 is sputtered over carbon mask material 351, and non-nucleated growth of material 352 promotes removal of portion 358 of material 352 with removal (e.g., ashing) of carbon mask material 351.

FIG. 4E illustrates stack upper portion 301B masked by material 352 and dielectric 323 adjacent lower portion 301A unmasked in workpiece or device 100, in accordance with some embodiments, for example, following a performance of masking operation 210 or 240. Dielectric 323 adjacent portion 301A is exposed below height H₁. No blanket mask material is present below height H₁ and over dielectric 323. The blanket mask material may be removed by any suitable means, such as a selective dry etch. Mask material 352 is over dielectric 323 above height H₁, adjacent upper portion 301B. Lateral portions of mask material 352 are absent.

FIG. 4F shows stack portion 301A unmasked and stack portion 301B masked by material 352 in workpiece or device 100, in accordance with some embodiments, for example, following a performance of masking operation 210 or 240. Channel layers 320A and sacrificial layers 320B in stack portion 301A are exposed below height H₁. Dielectric 323 is absent immediately adjacent portion 301A below height H₁. Dielectric 323 remains adjacent substrate 199. Dielectric 323 may be removed, and layers 320A, 320B in stack portion 301A (not masked by material 352) may be exposed, below height H₁ by an isotropic, selective etch of dielectric 323. Dielectric 323 may be removed by any suitable means.

Returning to FIG. 2, methods 200 continue at operation 270 by removing previously retained sections of the first material layers in the second portion. The previously retained sections may be those sections remaining of the sacrificial, first material layers between the end sections removed during a recess or dimple etch. Removing remaining or retained sections of the first material layers in the second portion (e.g., sections of sacrificial layers extending between spacers) may release retained channel layers in the second portion. The retained channel layers (e.g., retained second material layers between sacrificial, first material layers) are first nanoribbons in the second portion.

Any suitable means may be employed to remove the remaining, previously retained sections, for example, an isotropic, selective etch. The remaining sections of sacrificial layers in the non-masked second portion may be removed by a wet or dry, isotropic etch of the exposed sacrificial layers that is selective to the channel material layers to be retained. In some embodiments, this etch releasing the retained channel layers in the second portion utilizes a same or similar chemistry as the recess or dimple etch of operation 220.

In the example of FIG. 4F, sacrificial material layers 320B in the exposed second portion 301A have a same or similar composition as substrate 199. For example, material layers 320B may be predominantly silicon (e.g., between silicon germanium layers 320A), substrate 199 may be silicon, and a selective isotropic etch removing sacrificial layers 320B may also recess substrate 199 while retaining channel layers 320A (the isotropic etch being selective to the channel material, e.g., silicon germanium).

FIG. 4G illustrates channel layers 320A in portion 301A released and exposed and stack portion 301B masked by material 352 in workpiece or device 100, in accordance with some embodiments, for example, following a performance of removing operation 270. Substrate 199 is recessed (e.g., down below an upper surface of dielectric 323 to either side of substrate 199) with a distance D₄ between substrate 199 and a lower surface of a lowermost channel layer 320A in portion 301A (e.g., at a midpoint of lowermost channel layer 320A). A distance D₂ is between released channel layers 320A in portion 301A. In some embodiments, distance D₄ is one-and-a-half times or more than distance D₂.

Returning to FIG. 2, methods 200 continue at operation 280 by removing previously retained sections of the second material layers in the first portion. The previously retained sections may be those sections remaining of the sacrificial, second material layers between the end sections removed during a recess or dimple etch. Removing remaining or retained sections of the second material layers in the first portion (e.g., sections of sacrificial layers extending between spacers) may release retained channel layers in the first portion. The retained channel layers (e.g., retained first material layers between sacrificial, second material layers) are second nanoribbons in the first portion.

Any suitable means may be employed to remove the remaining, previously retained sections, for example, an isotropic, selective etch. The remaining sections of sacrificial layers in the first portion may be removed by a wet or dry, isotropic etch of the exposed sacrificial layers that is selective to the channel material layers to be retained. In some embodiments, this etch releasing the retained channel layers in the first portion utilizes a same or similar chemistry as the recess or dimple etch of operation 250. Releasing first material channel layers may follow first masking the second material channel layers in the second portion.

With second material channel layers released in the second stack portion and remaining sections of second material sacrificial layers in the first stack portion to be removed, the released second material channel layers may be protected by selectively growing a thin layer of the first material over the second material channel layers. In some embodiments (for example, embodiments where the retained second material channel layers in the second portion include silicon and germanium), releasing the first material channel layers (for example, of predominantly silicon) in the first portion (e.g., removing the remaining, previously retained sections of the sacrificial, second material layers of silicon and germanium in the first portion) includes depositing a layer of silicon over the retained second material channel layers (e.g., of silicon and germanium). In some such embodiments, the sacrificial, second material layers (e.g., of silicon and germanium) in the first portion are selectively removed. For example, an isotropic etch selective to the first material channel layers may remove exposed second material sacrificial layers. This etch selective to the first material (e.g., pure silicon) may use the chemistry of the recess etch of operation 250 to remove the second material (e.g., silicon and germanium).

The layer of silicon deposited over the retained second material channel layers (e.g., of silicon and germanium) may be grown by any suitable means and to any suitable thickness. In some embodiments, the silicon is selectively deposited on silicon germanium of the second material channel layers. In some embodiments, the layer of silicon is deposited to a thickness of 1 nm or less, for example, 5-10 Å thick. A maximum thickness of 10 Å may ensure that the layer of silicon is deposited on and between the channel layers with sufficient clearance (e.g., for consistent and satisfactory deposition and subsequent removal). A minimum thickness of 5 Å may ensure that the layer of silicon is sufficiently thick to provide satisfactory protection of the underlying channel material.

FIG. 4H shows channel layers 320A in portion 301A released and enveloped by masking layer 423 in workpiece or device 100, in accordance with some embodiments, for example, during a performance of removing operation 280. Layer 423 is conformal on and around channel layers 320A in portion 301A, as well as at an interface between portions 301A, 301B, on a lower surface of a lowermost sacrificial layer 320A in portion 301B.

FIG. 4I illustrates mask material 351 over stack 121 of layers 320, including on and over mask material 352, on and over layer 423 on channel layers 320A in portion 301A, and on and over substrate 199 and dielectric 323, in workpiece or device 100, in accordance with some embodiments, for example, during a performance of removing operation 280. Mask material 351 is between channel layers 320A in portion 301A. Stack 121 may be masked much as previously described, e.g., at operation 210 or 240, for example, in preparation for releasing channel layers 320B. In many embodiments, mask material 351 is a hardmask material 351, for example, including carbon.

FIG. 4J shows mask material 351 up to height H₁, on and over (and between) layers 423 on channel layers 320A in portion 301A of stack 121, and mask material 352 over portion 301B in workpiece or device 100, in accordance with some embodiments, for example, during a performance of removing operation 280. Mask material 352 covers dielectric 323 adjacent portion 301B, over height H₁. In many embodiments, mask material 351 is recessed down to height H₁, for example, much as described at masking operation 210.

FIG. 4K illustrates dielectric 323 exposed over portion 301, mask material 351 up to height H₁, on and over (and between) layers 423 on channel layers 320A in portion 301A of stack 121, in workpiece or device 100, in accordance with some embodiments, for example, during a performance of removing operation 280. No mask material is present over dielectric 323 adjacent portion 301B. The conformal mask material no longer present over dielectric 323 and portion 301B may be removed by a dry, selective etch (or any other suitable means).

FIG. 4L shows layers 320A, 320B of upper portion 301B exposed and mask material 351 adjacent portion 301A and up to height H₁, between portions 301A, 301B, in workpiece or device 100, in accordance with some embodiments, for example, during a performance of removing operation 280. Channel layers 320B and sacrificial layers 320A of upper portion 301B are exposed, e.g., in preparation for the release of channel layers 320B. No isolation dielectric is over portion 301B. The isolation dielectric may be removed by an isotropic, selective etch (or any other suitable means).

FIG. 4M illustrates channel layers 320B of upper portion 301B released, over mask material 351 adjacent portion 301A up to height H₁, in workpiece or device 100, in accordance with some embodiments, for example, following a performance of removing operation 280. No sacrificial material is present in upper portion 301B between channel layers 320B. The sacrificial material may be removed by an isotropic, selective etch (or any other suitable means), e.g., as described at removing operation 280.

FIG. 4N shows channel layers 320A, 320B of lower and upper portions 301A, 301B released, with no hardmask material present adjacent portion 301A, in workpiece or device 100, in accordance with some embodiments, for example, following a performance of removing operation 280. Substrate 199 and dielectric 323 are exposed, without any cover of mask material. Masking layers 423 remain on, over, and between channel layers 320A in portion 301A and at an interface between portions 301A, 301B, approximately at height H₁. The blanket mask material may be removed by any suitable means, for example, much as described at masking operation 210.

FIG. 4O illustrates channel layers 320A, 320B of lower and upper portions 301A, 301B released, with conformal gate dielectric layer 123 over layers 320A, 320B, and without any sacrificial mask material present on any of layers 320A, 320B, in workpiece or device 100, in accordance with some embodiments, for example, following a performance of removing operation 280. Gate insulator layer 123 is over channel layers 320A, 320B (and may be over substrate 199). Substrate 199 and dielectric 323 are exposed, without any cover of mask material. Channel layers 320A in portion 301A are advantageously lacking coverage from any sacrificial masking layers.

Any previous masking layer (e.g., of silicon) may be removed from layers 320A, 320B by any suitable means, for example, by a (wet or dry) selective, isotropic etch with a chemistry similar to the recess etch described at removing operation 220. In some embodiments, a clean (or preclean) of layers 320A, 320B oxidizes the masking layer and strips off the oxidized layer. In some such embodiments, the oxidization is repeated and provides a protective (e.g., passivation) layer over channel layers 320A, 320B.

FIG. 4P shows stack 121 of channel layers 320A, 320B of lower and upper portions 301A, 301B as stack 121 of nanoribbons 120A, 120B and with additional constituents and thickness in gate dielectric layer 123, in workpiece or device 100, in accordance with some embodiments, for example, following an embodiment of a performance of methods 200. Channel layers 320A, 320B are vertically aligned nanoribbons 120A, 120B in stack 121.

Gate layer 123 may be supplemented as desired. In the example of FIG. 4P, layer 123 includes added material(s), such as a high-K dielectric or ferroelectric layer as an outer portion of layer 123. Other material(s) may be added to layer 123, such as dipole dopants, etc., for example, to adjust a permittivity of layer 123 (or otherwise tune a threshold voltage VT of transistor structures).

Further processing, such as the formation of a gate electrode by the deposition of gate metal(s) over gate dielectric layer 123, may complete the transistor structures shown at, for example, FIG. 1. The gate electrode and source and drain bodies shown at, for example, FIG. 1 may be coupled to interconnect layers over and/or under the transistor structures. The transistor structures may be coupled to front- and/or back-side interconnect layers.

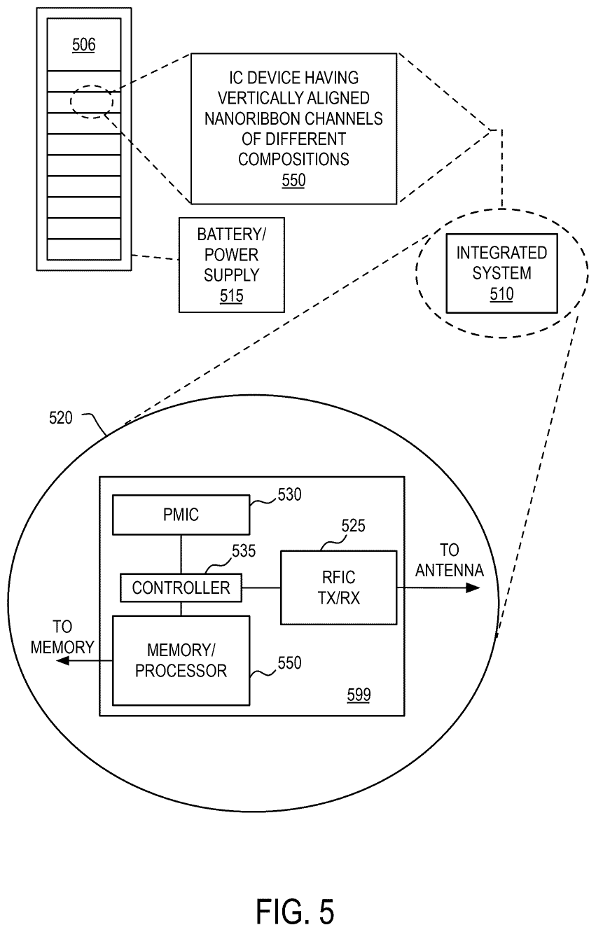

FIG. 5 illustrates a diagram of an example data server machine 506 employing an IC device having vertically aligned nanoribbon channels of different compositions, in accordance with some embodiments. Server machine 506 may be any commercial server, for example, including any number of high-performance computing platforms disposed within a rack and networked together for electronic data processing, which in the exemplary embodiment includes one or more devices 550 having vertically aligned nanoribbon channels of different compositions.

Also as shown, server machine 506 includes a battery and/or power supply 515 to provide power to devices 550, and to provide, in some embodiments, power delivery functions such as power regulation. Devices 550 may be deployed as part of a package-level integrated system 510. Integrated system 510 is further illustrated in the expanded view 520. In the exemplary embodiment, devices 550 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 550 is a microprocessor including a static RAM (SRAM) cache memory. As shown, device 550 may be an IC device having vertically aligned nanoribbon channels of different compositions, as discussed herein. Device 550 may be further coupled to (e.g., communicatively coupled to) a board, an interposer, or a substrate 599 along with, one or more of a power management IC (PMIC) 530, RF (wireless) IC (RFIC) 525 including a wideband RF (wireless) transmitter and/or receiver (TX/RX) (e.g., including a digital baseband and an analog front end module further includes a power amplifier on a transmit path and a low noise amplifier on a receive path), and a controller 535 thereof. In some embodiments, RFIC 525, PMIC 530, controller 535, and device 550 include having vertically aligned nanoribbon channels of different compositions.

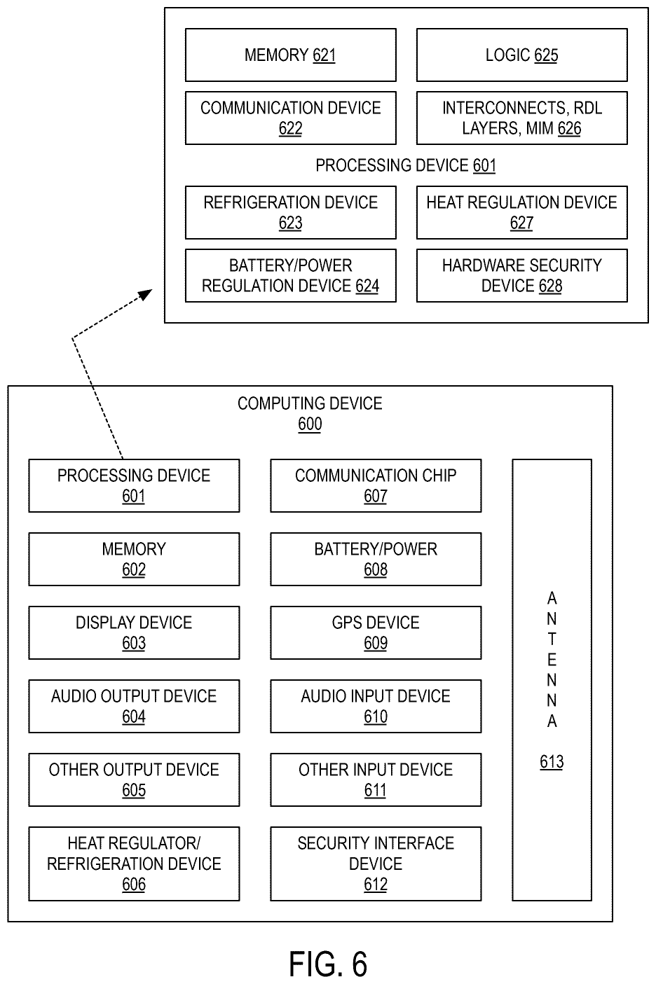

FIG. 6 is a block diagram of an example computing device 600, in accordance with some embodiments. For example, one or more components of computing device 600 may include any of the devices or structures discussed herein. A number of components are illustrated in FIG. 6 as being included in computing device 600, but any one or more of these components may be omitted or duplicated, as suitable for the application. In some embodiments, some or all of the components included in computing device 600 may be attached to one or more printed circuit boards (e.g., a motherboard). In some embodiments, various ones of these components may be fabricated onto a single system-on-a-chip (SoC) die. Additionally, in various embodiments, computing device 600 may not include one or more of the components illustrated in FIG. 6, but computing device 600 may include interface circuitry for coupling to the one or more components. For example, computing device 600 may not include a display device 603, but may include display device interface circuitry (e.g., a connector and driver circuitry) to which display device 603 may be coupled. In another set of examples, computing device 600 may not include an audio output device 604, other output device 605, global positioning system (GPS) device 609, audio input device 610, or other input device 611, but may include audio output device interface circuitry, other output device interface circuitry, GPS device interface circuitry, audio input device interface circuitry, audio input device interface circuitry, to which audio output device 604, other output device 605, GPS device 609, audio input device 610, or other input device 611 may be coupled.

Computing device 600 may include a processing device 601 (e.g., one or more processing devices). As used herein, the term “processing device” or “processor” indicates a device that processes electronic data from registers and/or memory to transform that electronic data into other electronic data that may be stored in registers and/or memory. Processing device 601 may include a memory 621, a communication device 622, a refrigeration device 623, a battery/power regulation device 624, logic 625, interconnects 626 (i.e., optionally including redistribution layers (RDL) or metal-insulator-metal (MIM) devices), a heat regulation device 627, and a hardware security device 628.

Processing device 601 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 600 may include a memory 602, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 602 includes memory that shares a die with processing device 601. This memory may be used as cache memory and may include embedded dynamic random-access memory (eDRAM) or spin transfer torque magnetic random-access memory (STT-MRAM).

Computing device 600 may include a heat regulation/refrigeration device 606. Heat regulation/refrigeration device 606 may maintain processing device 601 (and/or other components of computing device 600) at a predetermined low temperature during operation.

In some embodiments, computing device 600 may include a communication chip 607 (e.g., one or more communication chips). For example, the communication chip 607 may be configured for managing wireless communications for the transfer of data to and from computing device 600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 607 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 607 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 607 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 607 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 607 may operate in accordance with other wireless protocols in other embodiments. Computing device 600 may include an antenna 613 to facilitate wireless communications and/or to receive other wireless communications (such as AM or FM radio transmissions).

In some embodiments, communication chip 607 may manage wired communications, such as electrical, optical, or any other suitable communication protocols (e.g., the Ethernet). As noted above, communication chip 607 may include multiple communication chips. For instance, a first communication chip 607 may be dedicated to shorter-range wireless communications such as Wi-Fi or Bluetooth, and a second communication chip 607 may be dedicated to longer-range wireless communications such as GPS, EDGE, GPRS, CDMA, WiMAX, LTE, EV-DO, or others. In some embodiments, a first communication chip 607 may be dedicated to wireless communications, and a second communication chip 607 may be dedicated to wired communications.

Computing device 600 may include battery/power circuitry 608. Battery/power circuitry 608 may include one or more energy storage devices (e.g., batteries or capacitors) and/or circuitry for coupling components of computing device 600 to an energy source separate from computing device 600 (e.g., AC line power).

Computing device 600 may include a display device 603 (or corresponding interface circuitry, as discussed above). Display device 603 may include any visual indicators, such as a heads-up display, a computer monitor, a projector, a touchscreen display, a liquid crystal display (LCD), a light-emitting diode display, or a flat panel display, for example.

Computing device 600 may include an audio output device 604 (or corresponding interface circuitry, as discussed above). Audio output device 604 may include any device that generates an audible indicator, such as speakers, headsets, or earbuds, for example.

Computing device 600 may include an audio input device 610 (or corresponding interface circuitry, as discussed above). Audio input device 610 may include any device that generates a signal representative of a sound, such as microphones, microphone arrays, or digital instruments (e.g., instruments having a musical instrument digital interface (MIDI) output).

Computing device 600 may include a GPS device 609 (or corresponding interface circuitry, as discussed above). GPS device 609 may be in communication with a satellite-based system and may receive a location of computing device 600, as known in the art.

Computing device 600 may include other output device 605 (or corresponding interface circuitry, as discussed above). Examples of the other output device 605 may include an audio codec, a video codec, a printer, a wired or wireless transmitter for providing information to other devices, or an additional storage device.

Computing device 600 may include other input device 611 (or corresponding interface circuitry, as discussed above). Examples of the other input device 611 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 600 may include a security interface device 612. Security interface device 612 may include any device that provides security measures for computing device 600 such as intrusion detection, biometric validation, security encode or decode, access list management, malware detection, or spyware detection.

Computing device 600, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-6. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a plurality of first nanoribbons in a stack of nanoribbons, the first nanoribbons between and coupling first source and drain regions, a plurality of second nanoribbons in the stack of nanoribbons, the second nanoribbons between and coupling second source and drain regions, the second nanoribbons vertically aligned over the first nanoribbons, wherein one of the first and second nanoribbons include a semiconductor element absent from the other of the first and second nanoribbons, a gate electrode between the first source and drain regions and between the second source and drain regions, the first and second nanoribbons extending through the gate electrode, first insulators between the first source and drain regions, the gate electrode between the first insulators, the first nanoribbons extending through the first insulators, and second insulators between the second source and drain regions, the gate electrode between the second insulators, the second nanoribbons extending through the second insulator, wherein a first composition of the first insulator is different than a second composition of the second insulator.

In one or more second embodiments, further to the first embodiments, the stack of nanoribbons includes a first pitch between an uppermost of the first nanoribbons and a lowermost of the second nanoribbons, and the first pitch is at least one-and-a-half times a second pitch between the first nanoribbons.

In one or more third embodiments, further to the first or second embodiments, an uppermost of the first nanoribbons and a lowermost of the second nanoribbons are separated by a first distance, individual ones of the second nanoribbons are separated by a second distance, and the first distance is at least twice the second distance.

In one or more fourth embodiments, further to the first through third embodiments, the one of the first and second nanoribbons includes germanium, and germanium is the semiconductor element absent in the other of the first and second nanoribbons.

In one or more fifth embodiments, further to the first through fourth embodiments, a first pair of the first or second source and drain regions includes silicon and an n-type dopant, and a second pair of the first or second source and drain regions includes silicon, germanium, and a p-type dopant.

In one or more sixth embodiments, further to the first through fifth embodiments, individual ones of the first nanoribbons are separated by a first distance, the stack of nanoribbons is over a substrate, an uppermost surface of the substrate and a lowermost of the first nanoribbons are separated by a second distance, and the second distance is at least one-and-a-half times the first distance.

In one or more seventh embodiments, an apparatus includes first source and drain regions coupled by a plurality of first nanoribbons, second source and drain regions coupled by a plurality of second nanoribbons, a stack of vertically aligned nanoribbons including the first and second nanoribbons, wherein the first nanoribbons include silicon and germanium, the second nanoribbons include silicon, and germanium is absent in the second nanoribbons, and a gate electrode between first and second insulators, the first insulators between the first source and drain regions, the second insulators between the second source and drain regions, wherein the first and second nanoribbons extend through the gate electrode, and a first composition of the first insulator is different than a second composition of the second insulator.

In one or more eighth embodiments, further to the seventh embodiments, the first source and drain regions include silicon, germanium, and a p-type dopant, and the second source and drain regions include silicon, and an n-type dopant.

In one or more ninth embodiments, further to the seventh or eighth embodiments, the stack of vertically aligned nanoribbons includes a first pitch between an uppermost nanoribbon of a lower plurality of the first and second nanoribbons and a lowermost nanoribbon of an upper plurality of the first and second nanoribbons, and the first pitch is at least one-and-a-half times a second pitch between the first nanoribbons.

In one or more tenth embodiments, further to the seventh through ninth embodiments, the uppermost nanoribbon of the lower plurality and the lowermost nanoribbon of the upper plurality are separated by a first distance, individual ones of the second nanoribbons are separated by a second distance, and the first distance is at least twice the second distance.

In one or more eleventh embodiments, further to the seventh through tenth embodiments, individual ones of the first or second nanoribbons in the lower plurality are separated by a third distance, the stack of vertically aligned nanoribbons is over a substrate, an uppermost surface of the substrate and a lowermost nanoribbon of the lower plurality are separated by a fourth distance, and the fourth distance is at least one-and-a-half times the third distance.

In one or more twelfth embodiments, a method includes masking a first portion of a stack of alternating first and second material layers, the first portion of the stack vertically aligned with a second portion of the stack, removing first end sections of the first material layers in the second portion, depositing a first insulator at least adjacent first retained sections of the first material layers in the second portion, between retained second material layers, masking the second portion of the stack, removing second end sections of the second material layers in the first portion, depositing a second insulator at least adjacent second retained sections of the second material layers in the first portion, between retained first material layers, removing the first retained sections of the first material layers in the second portion, wherein the retained second material layers are first nanoribbons, and removing the second retained sections of the second material layers in the first portion, wherein the retained first material layers are second nanoribbons.

In one or more thirteenth embodiments, further to the twelfth embodiments, also including forming the stack of the alternating first and second material layers, wherein the forming the stack includes alternately depositing the first material layers including silicon and the second material layers including silicon and germanium.

In one or more fourteenth embodiments, further to the twelfth or thirteenth embodiments, the removing the second retained sections of the second material layers in the first portion includes depositing a layer of silicon over the retained second material layers including silicon and germanium in the second portion, and selectively removing the second material layers including silicon and germanium in the first portion.

In one or more fifteenth embodiments, further to the twelfth through fourteenth embodiments, also including forming the stack of the alternating first and second material layers, wherein the forming the stack includes alternately depositing the first and second material layers in the second portion of the stack before alternately depositing the first and second material layers in the first portion of the stack, over the second portion of the stack, and the forming the stack includes depositing an uppermost first or second material layer of the second portion or a lowermost first or second material layer of the first portion to a first thickness greater than a second thickness of a lowermost first or second material layer of the second portion.

In one or more sixteenth embodiments, further to the twelfth through fifteenth embodiments, the depositing the second insulator deposits the second insulator with a first composition different than a second composition of the first insulator.

In one or more seventeenth embodiments, further to the twelfth through sixteenth embodiments, the masking the first portion of the stack includes depositing and recessing a mask material to a level adjacent an uppermost first or second material layer of the first portion and a lowermost first or second material layer of the second portion.

In one or more eighteenth embodiments, further to the twelfth through seventeenth embodiments, the masking the first portion of the stack includes depositing and recessing a first mask material to a level adjacent an uppermost first or second material layer of the second portion and a lowermost first or second material layer of the first portion, depositing a second mask material over the first portion and a lateral surface of the first mask material, and removing the first mask material.

In one or more nineteenth embodiments, further to the twelfth through eighteenth embodiments, the depositing the second mask material over the first mask material and the first portion includes a physical vapor deposition of the second mask material over a sidewall of the first portion and a lateral surface of the first mask material, the second mask material including a metal, the first mask material including carbon, and the removing the first mask material includes removing the second mask material deposited over the lateral surface of the first mask material.

In one or more twentieth embodiments, further to the twelfth through nineteenth embodiments, the depositing the first or second insulator at least adjacent the first or second retained sections includes depositing the first or second insulator over the stack and exposing the first and second material layers by recessing the first or second insulator.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a plurality of first nanoribbons in a stack of nanoribbons, the first nanoribbons between and coupling first source and drain regions;
a plurality of second nanoribbons in the stack of nanoribbons, the second nanoribbons between and coupling second source and drain regions, the second nanoribbons vertically aligned over the first nanoribbons, wherein one of the first and second nanoribbons comprise a semiconductor element absent from the other of the first and second nanoribbons;
a gate electrode between the first source and drain regions and between the second source and drain regions, the first and second nanoribbons extending through the gate electrode;
first insulators between the first source and drain regions, the gate electrode between the first insulators, the first nanoribbons extending through the first insulators; and
second insulators between the second source and drain regions, the gate electrode between the second insulators, the second nanoribbons extending through the second insulator, wherein a first composition of the first insulator is different than a second composition of the second insulator.

2. The apparatus of claim 1, wherein:
the stack of nanoribbons comprises a first pitch between an uppermost of the first nanoribbons and a lowermost of the second nanoribbons; and
the first pitch is at least one-and-a-half times a second pitch between the first nanoribbons.

3. The apparatus of claim 1, wherein:
an uppermost of the first nanoribbons and a lowermost of the second nanoribbons are separated by a first distance;
individual ones of the second nanoribbons are separated by a second distance; and
the first distance is at least twice the second distance.

4. The apparatus of claim 1, wherein the one of the first and second nanoribbons comprises germanium, and germanium is the semiconductor element absent in the other of the first and second nanoribbons.

5. The apparatus of claim 4, wherein:
a first pair of the first or second source and drain regions comprises silicon and an n-type dopant; and
a second pair of the first or second source and drain regions comprises silicon, germanium, and a p-type dopant.

6. The apparatus of claim 1, wherein:
individual ones of the first nanoribbons are separated by a first distance;
the stack of nanoribbons is over a substrate;
an uppermost surface of the substrate and a lowermost of the first nanoribbons are separated by a second distance; and
the second distance is at least one-and-a-half times the first distance.

7. An apparatus, comprising:
first source and drain regions coupled by a plurality of first nanoribbons;
second source and drain regions coupled by a plurality of second nanoribbons;
a stack of vertically aligned nanoribbons comprising the first and second nanoribbons, wherein the first nanoribbons comprise silicon and germanium, the second nanoribbons comprise silicon, and germanium is absent in the second nanoribbons; and
a gate electrode between first and second insulators, the first insulators between the first source and drain regions, the second insulators between the second source and drain regions, wherein the first and second nanoribbons extend through the gate electrode, and a first composition of the first insulator is different than a second composition of the second insulator.

8. The apparatus of claim 7, wherein:
the first source and drain regions comprise silicon, germanium, and a p-type dopant; and
the second source and drain regions comprise silicon, and an n-type dopant.

9. The apparatus of claim 8, wherein:
the stack of vertically aligned nanoribbons comprises a first pitch between an uppermost nanoribbon of a lower plurality of the first and second nanoribbons and a lowermost nanoribbon of an upper plurality of the first and second nanoribbons; and
the first pitch is at least one-and-a-half times a second pitch between the first nanoribbons.

10. The apparatus of claim 9, wherein:
the uppermost nanoribbon of the lower plurality and the lowermost nanoribbon of the upper plurality are separated by a first distance;
individual ones of the second nanoribbons are separated by a second distance; and
the first distance is at least twice the second distance.

11. The apparatus of claim 10, wherein:
individual ones of the first or second nanoribbons in the lower plurality are separated by a third distance;
the stack of vertically aligned nanoribbons is over a substrate;
an uppermost surface of the substrate and a lowermost nanoribbon of the lower plurality are separated by a fourth distance; and
the fourth distance is at least one-and-a-half times the third distance.

12. A method, comprising:
masking a first portion of a stack of alternating first and second material layers, the first portion of the stack vertically aligned with a second portion of the stack;
removing first end sections of the first material layers in the second portion;
depositing a first insulator at least adjacent first retained sections of the first material layers in the second portion, between retained second material layers;
masking the second portion of the stack;
removing second end sections of the second material layers in the first portion;
depositing a second insulator at least adjacent second retained sections of the second material layers in the first portion, between retained first material layers;
removing the first retained sections of the first material layers in the second portion, wherein the retained second material layers are first nanoribbons; and
removing the second retained sections of the second material layers in the first portion, wherein the retained first material layers are second nanoribbons.

13. The method of claim 12, further comprising forming the stack of the alternating first and second material layers, wherein the forming the stack comprises alternately depositing the first material layers comprising silicon and the second material layers comprising silicon and germanium.

14. The method of claim 13, wherein the removing the second retained sections of the second material layers in the first portion comprises:
depositing a layer of silicon over the retained second material layers comprising silicon and germanium in the second portion; and
selectively removing the second material layers comprising silicon and germanium in the first portion.

15. The method of claim 12, further comprising forming the stack of the alternating first and second material layers, wherein:
the forming the stack comprises alternately depositing the first and second material layers in the second portion of the stack before alternately depositing the first and second material layers in the first portion of the stack, over the second portion of the stack; and
the forming the stack comprises depositing an uppermost first or second material layer of the second portion or a lowermost first or second material layer of the first portion to a first thickness greater than a second thickness of a lowermost first or second material layer of the second portion.

16. The method of claim 12, wherein the depositing the second insulator deposits the second insulator with a first composition different than a second composition of the first insulator.

17. The method of claim 12, wherein the masking the first portion of the stack comprises depositing and recessing a mask material to a level adjacent an uppermost first or second material layer of the first portion and a lowermost first or second material layer of the second portion.

18. The method of claim 12, wherein the masking the first portion of the stack comprises:
depositing and recessing a first mask material to a level adjacent an uppermost first or second material layer of the second portion and a lowermost first or second material layer of the first portion;
depositing a second mask material over the first portion and a lateral surface of the first mask material; and
removing the first mask material.

19. The method of claim 18, wherein:
the depositing the second mask material over the first mask material and the first portion comprises a physical vapor deposition of the second mask material over a sidewall of the first portion and a lateral surface of the first mask material, the second mask material comprising a metal, the first mask material comprising carbon; and
the removing the first mask material comprises removing the second mask material deposited over the lateral surface of the first mask material.

20. The method of claim 12, wherein the depositing the first or second insulator at least adjacent the first or second retained sections comprises depositing the first or second insulator over the stack and exposing the first and second material layers by recessing the first or second insulator.
